(19) United States
(12) Patent Application Publication
(10) Pub. No.: US 2014/0299163 A1
(43) Pub. Date: Oct. 9, 2014

(54) SUBSTRATE PROCESSING METHOD

(71) Applicant: EBARA CORPORATION, Tokyo (JP)

(72) Inventor: Tomoatsu ISHIBASHI, Tokyo (JP)

(21) Appl. No.: 14/242,797

(22) Filed: Apr. 1, 2014

(30) Foreign Application Priority Data
Apr. 3, 2013 (JP) 2013-077430

(51) Int. Cl. H01L 21/02

(52) U.S. Cl. CPC H01L 21/02052
USPC 134/33

(57) ABSTRACT

A substrate processing method which can reduce electrostatic charge of a substrate surface is disclosed. The substrate processing method includes: performing a first processing step of supplying a liquid containing pure water onto a substrate while rotating the substrate; and then performing a second processing step of supplying the liquid onto the substrate, while rotating the substrate, under a condition in which a rate of increase in a surface potential of the substrate is lower than that in the first processing step.

### CROSS REFERENCE TO RELATED APPLICATION

This document claims priority to Japanese Patent Application Number 2013-077430 filed Apr. 3, 2013, the entire contents of which are hereby incorporated by reference.

### BACKGROUND

In a manufacturing process of a semiconductor device, various films having different physical properties are formed on a silicon substrate and these films are subjected to various processes, thus forming fine metal interconnects, For example, in a damascene interconnect forming process, interconnect trenches are formed in a film, and the interconnect trenches are then filled with metal. Thereafter, an excessive metal is removed by chemical mechanical polishing (CMP), so that metal interconnects are formed. A variety of films including a metal film, a barrier film, and a dielectric film exist on a surface of the substrate that has been manufactured through such a damascene interconnect forming process.

A CMP apparatus (or a polishing apparatus) for polishing a substrate typically includes a substrate cleaning apparatus for cleaning and drying a polished substrate. Cleaning of the substrate is performed by bringing a cleaning tool, such as a roll sponge, into sliding contact with the substrate while rotating the substrate. After cleaning of the substrate, ultrapure water (DIW) is supplied onto the rotating substrate, thereby rinsing the substrate. Before the substrate is dried, the ultrapure water is further supplied onto the surface of the rotating substrate to rinse the surface of the substrate.

It is commonly known that the ultrapure water, to be supplied onto the rotating substrate, has a high specific resistance value (≧15M Ω•cm) and that the surface of the substrate is electrostatically charged by the contact with the ultrapure water. Practically, experiments have confirmed that the surface of the substrate, on which metal interconnects and dielectric films are formed, is electrostatically charged as a result of supply of the ultrapure water onto the substrate surface. Possible causes of such a phenomenon of the electrostatic charge may include the fact that the ultrapure water has a high specific resistance value and that the ultrapure water forms a flow on the rotating substrate, although the causes are uncertain. The electrostatic charge of the substrate surface may cause reattachment of particles that have been once removed by the cleaning process of the substrate surface, and may cause destruction of devices due to electrostatic discharge. Further, in devices having copper interconnects, copper (Cu) itself is liable to migrate under the influence of the surface charge, and may be attached to a dielectric film Consequently, shortcut between the interconnects or leakage of current may occur, and/or poor adhesion between the copper interconnects and the dielectric film may occur.

### SUMMARY OF THE INVENTION

It is an object to provide a substrate processing method which can suppress electrostatic charge of a substrate surface.

A method of processing (e.g., rinsing) a substrate with a liquid, such as pure water or ultrapure water, is provided. Especially, a method of processing a substrate while suppressing electrostatic charge of a structure (e.g., a dielectric film, a metallic film, or a device including a dielectric film and a metallic film) formed on the substrate is provided.

In an embodiment, a substrate processing method includes: performing a first processing step of supplying a liquid containing pure water onto a substrate while rotating the substrate; and then performing a second processing step of supplying the liquid onto the substrate, while rotating the substrate, under a condition in which a rate of increase in a surface potential of the substrate is lower than that in the first processing step.

In an embodiment, a rotational speed of the substrate in the second processing step is lower than that in the first processing step, or a flow rate of the liquid supplied to the substrate in the second processing step is lower than that in the first processing step.

In an embodiment, the liquid is pure water.

In an embodiment, the pure water is ultrapure water having a specific resistance of not less than 15 MΩ•cm.

In an embodiment, the liquid is a chemical liquid diluted with ultrapure water.

The present inventor has found from experiments that a charging tendency of the substrate varies according to a change in particular processing conditions. Specifically, in a multi-step processing of a substrate, the electrostatic charge of the substrate is suppressed, i.e., an increase in the surface potential of the substrate is suppressed if a subsequent processing step is performed under conditions such that a rate of increase in the surface potential of the substrate is lower than that in a preceding processing step. According to the embodiments described above, the electrostatic charge of the substrate can be suppressed while performing multi-step processing of the substrate.

### BRIEF DESCRIPTION OF THE DRAWINGS

FIG. 1 is a diagram showing a polishing apparatus provided with polishing units, cleaning units, and a drying unit;

FIG. 2 is a perspective view of a first polishing unit;

FIG. 3 is a perspective view of a first cleaning unit (a substrate cleaning unit);

FIG. 4 is a graph showing results of experiments to examine a change in surface potential of a wafer when it is rotated at various speeds while the rotating wafer is supplied with pure water at a constant flow rate;

FIG. 5 is a graph showing results of experiments to examine how a charging tendency of a wafer during supply of the pure water onto the wafer varies depending on the rotational speed of the wafer;

FIG. 6 is a graph showing results of experiments to examine electrostatic charge of a wafer; and

FIG. 7 is a perspective view of a pen sponge-type substrate cleaning apparatus.

### DETAILED DESCRIPTION OF EMBODIMENTS

Embodiments will be described below with reference to the drawings.

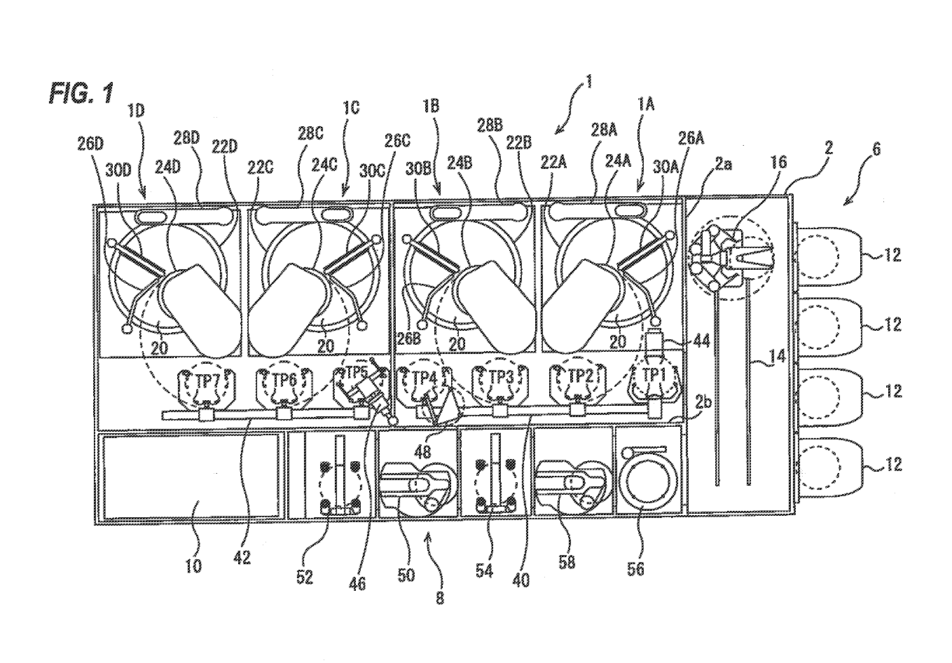

FIG. 1 is a view showing a polishing apparatus having a polishing unit, a cleaning unit, and a drying unit. This polishing apparatus is a substrate processing apparatus capable of performing a series of processes including polishing, cleaning, and drying of a wafer (or a substrate). As shown in FIG. 1, the polishing apparatus has a housing 2 in approximately a rectangular shape. An interior space of the housing 2 is divided by partitions 2a, 2b into a load-unload section 6, a polishing section L and a cleaning section 8. The polishing apparatus includes an operation controller 10 configured to control wafer processing operations.

The load-unload section 6 has load ports 12 on which wafer cassettes are placed, respectively. A plurality of wafers are stored in each wafer cassette, The load-unload section 6 has a moving mechanism 14 extending along an arrangement direction of the load ports 12. A transfer robot (loader) 16 is provided on the moving mechanism 14, so that the transfer robot 16 can move along the arrangement direction of the wafer cassettes. The transfer robot 16 moves on the moving mechanism 14 so as to access the wafer cassettes mounted to the load ports 12.

The polishing section 1 is an area where a wafer is polished. This polishing section 1 includes a first polishing unit 1A, a second polishing unit 1B, a third polishing unit 1C, and a fourth polishing unit 1D. The first polishing unit 1A includes a first polishing table 22A to which a polishing pad 20, having a polishing surface, is attached, a first top ring 24A for holding a wafer and pressing the wafer against the polishing pad 20 on the first polishing table 22A so as to polish the wafer, a first polishing liquid supply nozzle 26A for supplying a polishing liquid (e.g., slurry) and a dressing liquid (e.g., pure water) onto the polishing pad 20, a first dressing unit 28A for dressing the polishing surface of the polishing pad 20, and a first atomizer 30A for ejecting a mixture of a liquid (e.g., pure water) and a gas (e.g., nitrogen gas) or a liquid (e.g., pure water), in an atomized state, onto the polishing surface of the polishing pad 20.

Similarly, the second polishing unit 1B includes a second polishing table 22B to which a polishing pad 20 is attached, a second top ring 24B, a second polishing liquid supply nozzle 26B, a second dressing unit 28B, and a second atomizer 30B. The third polishing unit 1C includes a third polishing table 22C to which a polishing pad 20 is attached, a third top ring 24C, a third polishing liquid supply nozzle 26C, a third dressing unit 28C, and a third atomizer 30C. The fourth polishing unit 1D includes a fourth polishing table 22D to which a polishing pad 20 is attached, a fourth top ring 24D, a fourth polishing liquid supply nozzle 26D, a fourth dressing unit 28D, and a fourth atomizer 30D.

A first linear transporter 40 is disposed adjacent to the first polishing unit 1A and the second polishing unit 1B. The first linear transporter 40 is a mechanism for transporting a wafer between four transfer positions (i.e., a first transfer position TP1, a second transfer position TP2, a third transfer position TP3 and a fourth transfer position TP4). A second linear transporter 42 is disposed adjacent to the third polishing unit 1C and the fourth polishing unit 1D. The second linear transporter 42 is a mechanism for transporting a wafer between three transfer positions (i.e., a fifth transfer position TP5, a sixth transfer position TP6, and a seventh transfer position TP7).

A lifter 44 for receiving the wafer from the transfer robot 16 is disposed adjacent to the first transfer position TP1. The wafer is transported from the transfer robot 16 to the first linear transporter 40 via the lifter 44. A shutter (not shown in the drawing) is provided on the partition 2a. This shutter is located between the lifter 44 and the transfer robot 16. When the wafer is to be transported, the shutter is opened to allow the transfer robot 16 to transport the wafer to the lifter 44.

The wafer is transported to the lifter 44 by the transfer robot 16, then transported from the lifter 44 to the first linear transporter 40, and further transported to the polishing units 1A, 1B by the first linear transporter 40. The top ring 24A of the first polishing unit 1A is movable between a position above the first polishing table 22A and the second transfer position TP2 by a swing motion of the top ring 24A. Therefore, the wafer is transferred to and from the top ring 24A at the second transfer position TP2.

Similarly, the top ring 24B of the second polishing unit 1B is movable between a position above the polishing table 22B and the third transfer position TP3, and the wafer is transferred to and from the top ring 24B at the third transfer position TP3. The top ring 24C of the third polishing unit 1C is movable between a position above the polishing table 22C and the sixth transfer position TP6, and the wafer is transferred to and from the top ring 24C at the sixth transfer position TP6. The top ring 24D of the fourth polishing unit 1D is movable between a position above the polishing table 22D and the seventh transfer position TP7, and the wafer is transferred to and from the top ring 24D at the seventh transfer position TP7.

A swing transporter 46 is provided between the first linear transporter 40, the second linear transporter 42, and the cleaning section 8. Transporting of the wafer from the first linear transporter 40 to the second linear transporter 42 is performed by the swing transporter 46. The wafer is transported to the third polishing unit 1C and/or the fourth polishing unit 1D by the second linear transporter 42.

A temporary stage 48 for the wafer W is disposed beside the swing transporter 46. This temporary stage 48 is mounted to a non-illustrated frame. As shown in FIG. 1, the temporary stage 48 is disposed adjacent to the first linear transporter 40 and located between the first linear transporter 40 and the cleaning section 8. The swing transporter 46 is configured to transport the wafer between the fourth transfer position TP4, the fifth transfer position TP5, and the temporary stage 48.

The wafer, once placed on the temporary stage 48, is transported to the cleaning section 8 by a first transfer robot 50 of the cleaning section 8. The cleaning section 8 includes a first cleaning unit 52 and a second cleaning unit 54 each for cleaning the polished wafer with a cleaning liquid, and a drying unit 56 for drying the cleaned wafer. The first transfer robot 50 is operable to transport the wafer from the temporary stage 48 to the first cleaning unit 52 and further transport the wafer from the first cleaning unit 52 to the second cleaning unit 54. A second transfer robot 58 is disposed between the second cleaning unit 54 and the drying unit 56. This second transfer robot 58 is operable to transport the wafer from the second cleaning unit 54 to the drying unit 56.

The dried wafer is removed from the drying unit 56 and returned to the wafer cassette by the transfer robot 16. In this manner, a series of processes including polishing, cleaning, and drying of the wafer is performed.

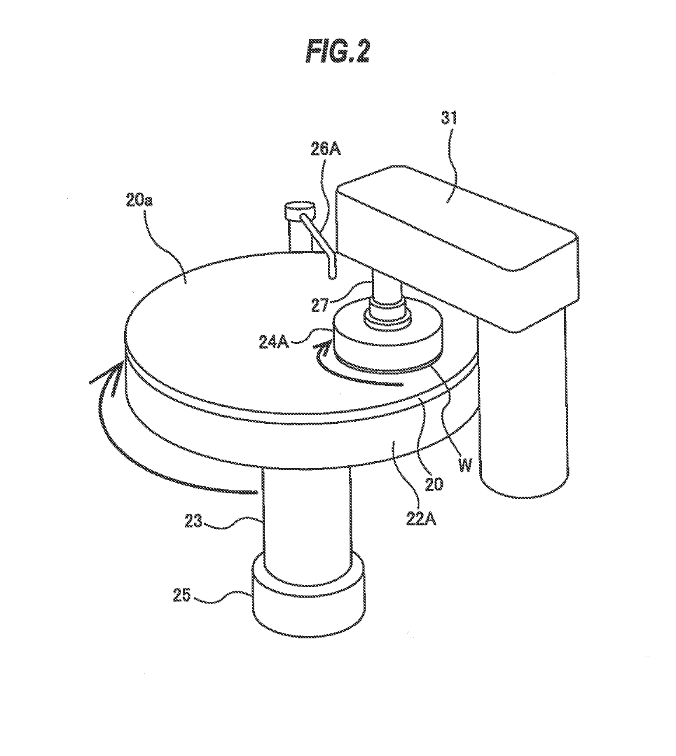

The first polishing unit 1A, the second polishing, unit 1B, the third polishing unit 1C, and the fourth polishing unit 1D have the same structure as each other. Therefore, the first polishing unit 1A will be described below. FIG. 2 is a schematic perspective view showing the first polishing unit 1A. As shown in FIG. 2, the first polishing unit 1A includes the polishing table 22A supporting the polishing pad 20, the top ring 24A for pressing the wafer W against the polishing pad 20, and the polishing liquid supply nozzle 26A for supplying the polishing liquid (or slurry) onto the polishing pad 20. In FIG. 2, illustration of the first dressing unit 28A and the first atomizer 30A is omitted.

The polishing table 22A is coupled via a table shaft 23 to a table motor 25 disposed below the polishing table 22A so that the polishing table 22A is rotated by the table motor 25 in a direction indicated by arrow. The polishing pad 20 is attached to an upper surface of the polishing table 22A. The polishing pad 20 has an upper surface, which provides a polishing surface 20a for polishing the wafer W. The top ring 24A is secured to a lower end of a top ring shaft 27. The top ring 24A is configured to be able to hold the wafer W on its lower surface by vacuum suction. The top ring shaft 27 is coupled to a rotating device (not shown) disposed in a top ring arm 31, so that the top ring 24A is rotated by the rotating device through the top ring shaft 27.

Polishing of the surface of the wafer W is performed as follows. The top ring 24A and the polishing table 22A are rotated in respective directions indicated by arrows, and the polishing liquid (e.g., the slurry) is supplied from the polishing liquid supply nozzle 26A onto the polishing pad 20. In this state, the wafer W is pressed against the polishing surface 20a of the polishing pad 20 by the top ring 24A. The surface of the wafer W is polished by a mechanical action of abrasive grains contained in the polishing liquid and a chemical action of a chemical component contained in the polishing liquid.

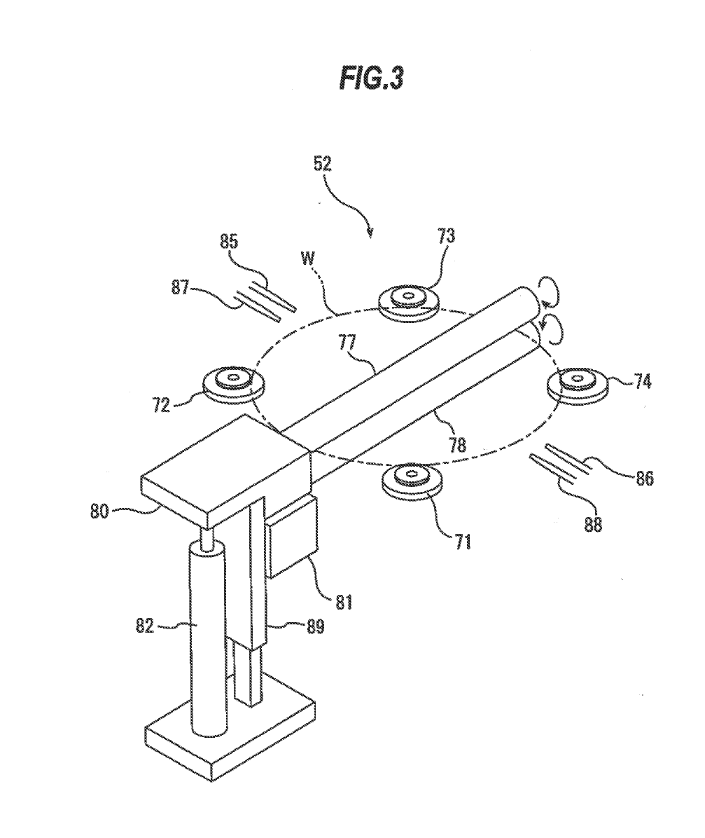

The first cleaning unit 52 and the second cleaning unit 54 have the same structure as each other. Therefore, the first cleaning unit 52 will be described below. FIG. 3 is a schematic perspective view showing the first cleaning unit (substrate cleaning apparatus) 52. As shown in FIG. 3, the first cleaning unit 52 includes four holding rollers 71, 72, 73, 74 for holding and rotating the wafer W horizontally, roll sponges (cleaning tools) 77, 78 configured to contact upper and lower surfaces of the wafer W, respectively, rotating devices 80, 81 for rotating the roll sponges 77, 78, upper pure water supply nozzles 85, 86 for supplying pure water (preferably, ultrapure water) onto the upper surface (the surface on which a dielectric film, a metallic film, or a structure, such as a device, including a dielectric film and a metallic film is formed) of the wafer W, and upper cleaning liquid supply nozzles 87, 88 for supplying a cleaning liquid (chemical liquid) onto the upper surface of the wafer W. Although not shown in FIG. 3, lower pure water supply nozzles for supplying pure water (preferably, ultrapure water) onto the lower surface of the wafer W, and lower cleaning liquid supply nozzles for supplying a cleaning liquid (chemical liquid) onto the lower surface of the wafer W are provided,

The holding rollers 71, 72, 73, 74 are configured to be movable in directions closer to and away from the wafer W by a non-illustrated moving mechanism (e.g., an air cylinder). The rotating device 80, which is configured to rotate the upper roll sponge 77, is mounted to a guide rail 89 that guides a vertical movement of the rotating device 80. The rotating device 80 is supported by an elevating device 82 so that the rotating device 80 and the upper roll sponge 77 are moved in the vertical direction by the elevating device 82. Although not shown in FIG. 3, the rotating device 81, which is configured to rotate the lower roll sponge 78, is also mounted to a guide rail. The rotating device 81 and the lower roll sponge 78 are moved vertically by an elevating device (not shown). A motor-drive mechanism employing a ball screw, an air cylinder, or the like is used as the elevating device. When the wafer W is to be cleaned, the roll sponges 77, 78 are moved closer to each other until the roll sponges 77, 78 contact the upper and lower surfaces of the wafer W, respectively.

A process of cleaning the wafer W will now be described. First, the wafer W is started rotating about its axis. Next, the cleaning liquid is started to be supplied from the upper cleaning liquid supply nozzles 87, 88 and the not-shown lower cleaning liquid supply nozzles onto the upper surface and the lower surface of the wafer W. While rotating the wafer W and supplying the cleaning liquids to the wafer W, the roll sponges 77, 78 are rotated about their horizontally-extending axes and rubbed against the upper and lower surfaces of the wafer W to scrub the upper and lower surfaces of the wafer W.

After the scrub-cleaning of the wafer W, rinsing of the wafer W is performed by supplying the pure water to the rotating wafer W. The rinsing of the wafer W may be performed while rubbing the roll sponges 77, 78 against the upper and lower surfaces of the wafer W or while keeping the roll sponges 77, 78 away from the upper and lower surfaces of the wafer W.

The wafer W that has been polished in the polishing section 1 is cleaned in the first cleaning unit 52 and the second cleaning unit 54 in the above-described manner. It is also possible to perform multi-step cleaning of a wafer with use of three or more cleaning units.

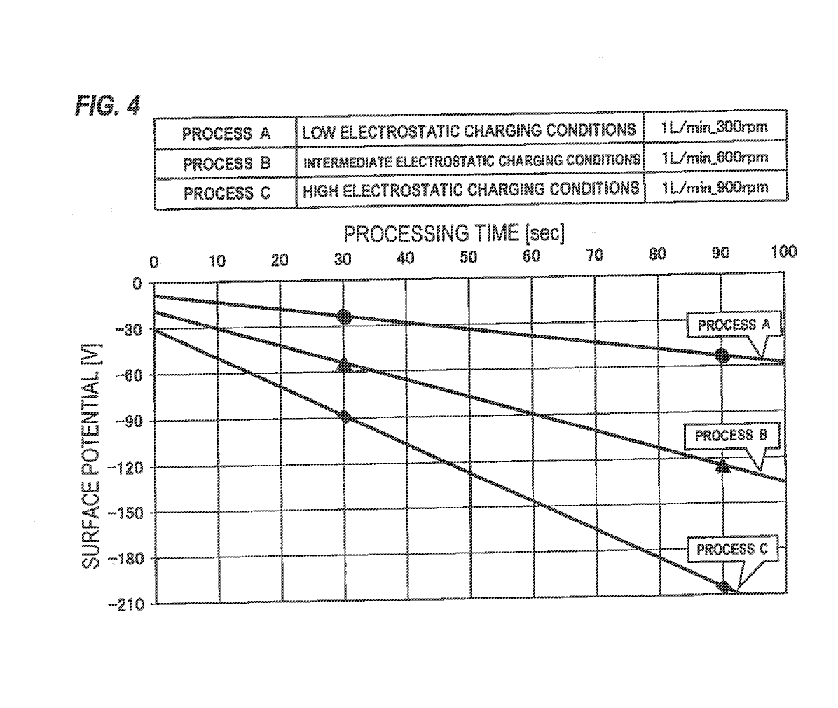

As is known in the art, a wafer is liable to be electrostatically charged when pure water, especially ultrapure water having a high specific resistance value (≧15 MΩ•cm), is supplied to the wafer during rinsing of the wafer. A charging tendency of the wafer varies depending on wafer rinsing conditions. In particular, a tendency of an increase in the surface potential (absolute value) varies depending on a rotational speed of the wafer and a flow rate of the pure water supplied to the wafer. FIG. 4 is a graph showing results of experiments that were conducted to examine a change in surface potential of a wafer when it is rotated at various speeds while the rotating wafer is supplied with the pure water at a constant flow rate. The wafer was rotated at 300 rpm in a process A; the wafer was rotated at 600 rpm in a process B; and the wafer was rotated at 900 rpm in a process C. The flow rate of pure water supplied was 1 L/min in all of the processes A, B and C.

As shown in FIG. 4, the charging tendency in the process C is higher than the charging tendency hi the process B, and the charging tendency in the processing B is higher the charging tendency in the process A. Thus, under the condition that the flow rate of the pure water is constant, a higher rotational speed of the wafer results in a greater increase in the surface potential of the wafer that varies with time. The expression “increase in the surface potential” herein refers to increase in the absolute value of the surface potential [V]. The expression “a rate of increase in the surface potential” herein refers to an amount of increase in the absolute value of the surface potential [V] per a predetermined processing time, or to an amount of increase in the absolute value of the surface potential [V] that varies depending on the processing time.

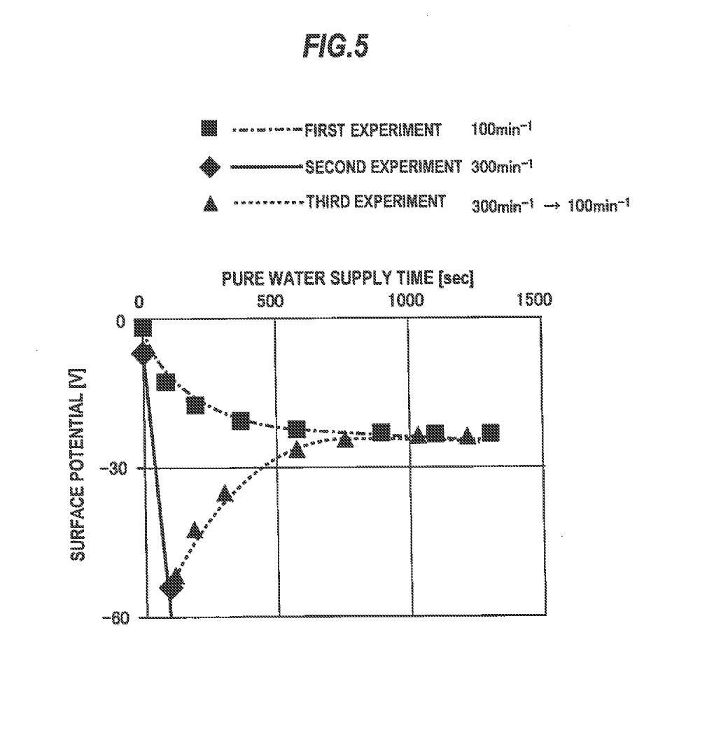

FIG. 5 is a graph showing results of experiments that were conducted to examine how the charging tendency of the wafer varies depending on the rinsing time under the condition of different rotational speeds of the wafer. The experiments were conducted under the condition that the pure water was supplied to the wafer at the same flow rate. In FIG, 5, a vertical axis represents the surface potential [V] of the wafer, and a horizontal axis represents a period of time [second] during which the pure water was supplied to the wafer, In a first experiment, the wafer was rinsed under low electrostatic charge conditions. Specifically, while the wafer was rotated at 100 rpm, the pure water was supplied to the surface of the wafer at a predetermined flow rate. In a second experiment, the wafer was rinsed under high electrostatic charge conditions. Specifically, while the wafer was rotated at 300 rpm, the pure water was supplied to the surface of the wafer at the predetermined flow rate. In a third experiment, the wafer was rinsed under high electrostatic charge conditions at an initial stage of rinsing, and then the wafer was rinsed under low electrostatic charge conditions. Specifically, while the wafer was rotated at 300 rpm, the pure water was supplied to the surface of the wafer at the predetermined flow rate at the initial stage of rinsing. Thereafter, while maintaining the same flow rate of the pure water supplied to the wafer, the rotational speed of the wafer was switched from 300 rpm to 100 rpm to perform the later-stage rinsing. The rinsing time, i.e., the pure water supply time, was the same among the first to third experiments.

As can be seen from the experimental results shown in FIG. 5, when the wafer was rotated at 300 rpm, the surface potential of the wafer rapidly increased with the pure water supply time (i.e., the rinsing time). After the rotational speed of the wafer was switched from 300 rpm to 100 rpm, the surface potential (absolute value) gradually decreased and eventually became approximately equal to the surface potential observed in the first experiment performed under the low electrostatic charge conditions. That is, after the rinsing conditions were switched from the high electrostatic charge conditions to the low electrostatic charge conditions, the charging tendency approaches one in the low electrostatic charge conditions. These experimental results indicate that the electrostatic charge of the wafer surface is not a mere accumulation of charges, and can vary depending on charging factors: the specific resistance of the pure water, the flow rate of the pure water supplied to the wafer; and the rotational speed of the wafer. The charging tendency of the wafer surface can be expressed as a time-dependent numerical value, i.e. a change in the surface potential with time. That is, the surface potential of the wafer during the rinsing process increases or decreases with the rinsing time (i.e., the pure water supply time) depending on the wafer rinsing conditions.

Based on the above-described experimental results, the present inventor has found that when performing cleaning of a wafer in multiple steps, the electrostatic charge of the wafer can be suppressed by appropriately changing the rinsing conditions in each cleaning step. More specifically, it has been found that the surface potential of the wafer tends to decrease in every subsequent rinsing step if the subsequent rinsing step is performed under conditions in which the wafer is less electrostatically charged than in the preceding rinsing step. This means that the electrostatic charge of the wafer can be suppressed. In contrast, the surface potential of the wafer tends to increase in every subsequent rinsing step if the subsequent rinsing step is performed under conditions in which the wafer is more electrostatically charged than in the preceding rinsing step.

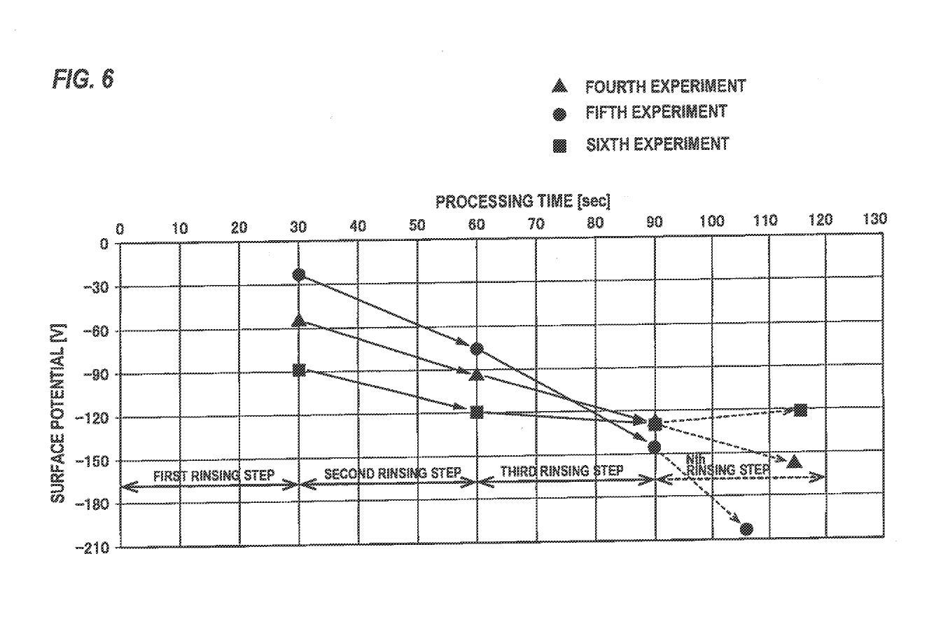

FIG. 6 is a graph showing results of experiments that were conducted to examine the electrostatic charge of a wafer. In the graph of FIG. 6, a vertical axis represents the surface potential [V] of the wafer, and a horizontal axis represents the processing time [second]. In the experiments, the wafer was subjected to a three-step cleaning process consisting of a first cleaning step, a second cleaning step, and a third cleaning step. In each cleaning step, the wafer was scrub-cleaned and the pure water was then supplied onto the wafer for 30 seconds to rinse the wafer. The surface potential of the wafer was measured after rinsing of the wafer. Hereinafter, rinsing of the wafer in the first cleaning step will be referred to as a first rinsing step, rinsing of the wafer in the second cleaning step will be referred to as a second rinsing step, and rinsing of the wafer in the third cleaning step will be referred to as a third rinsing step.

In a fourth experiment, the first rinsing step, the second rinsing step, and the third rinsing step were performed under the same conditions. In a fifth experiment, the second rinsing step was performed under conditions in which the wafer is more electrostatically charged than in the first rinsing step, and the third rinsing step was performed under conditions in which the wafer is more electrostatically charged than in the second rinsing step. In a sixth experiment, the second rinsing step was performed under conditions in which the wafer is less electrostatically charged than in the first rinsing step, and the third rinsing step was performed under conditions in which the wafer is less electrostatically charged than in the second rinsing step. As shown in FIG. 6, the charging tendency of the wafer varies with the change in the rinsing conditions that affect the electrostatic charge of the wafer. Dotted lines in FIG. 6 each indicates a charging tendency that can be expected in a hypothetical additional rinsing step which is assumed to be further performed under the above-described conditions in the respective experiments. Specifically, in the fourth experiment, the n+1-th rinsing step is performed under the same conditions as in the n-th rinsing step. In the fifth experiment, the n+1-th rinsing step is performed under conditions that the wafer is more electrostatically charged than in the n-th rinsing step. In the sixth experiment, the n+1-th rinsing step is performed under conditions that the wafer is less electrostatically charged than in the n-th rinsing step.

In a wafer rinsing step, electrostatic charge of a wafer depends on the rotational speed of the wafer and the flow rate of pure water supplied to the wafer. More specifically, the higher the rotational speed of the wafer is, the more the wafer is likely to be electrostatically charged (the more the surface potential of the wafer increases). The higher the flow rate of the pure water is, the more the wafer is likely to be electrostatically charged. In the fourth experiment, all the rinsing steps were performed under the same conditions in which the rotational speed of the wafer and the flow rate of the pure water were constant, whereas in the fifth and sixth experiments, the rotational speed of the wafer and/or the flow rate of pure water was varied in each rinsing step.

The graph of FIG, 6 indicates that in the fourth experiment the surface potential (which is an absolute value) of the wafer increases by the same amount in every rinsing step, that in the Ma experiment the rate of increase in the surface potential of the wafer increases (i.e., the electrostatic charge of the wafer is accelerated) in every subsequent rinsing step, and that in the sixth experiment the rate of increase in the surface potential of the wafer decreases in every subsequent rinsing step and, consequently, the electrostatic charge of the wafer is suppressed.

The present invention is based on the above findings. Specifically, a subsequent rinsing step is performed under conditions in which the rate of increase in the surface potential of a wafer is lower than that in the preceding rinsing step. For instance, a subsequent rinsing step is performed at a lower rotational speed of a wafer or at a lower flow rate of pure water supplied to the wafer as compared to the preceding rinsing step. Alternatively, a subsequent rinsing step may be performed at a lower rotational speed of a wafer and at a lower flow rate of pure water supplied to the wafer as compared to the preceding rinsing step. The electrostatic charge of the wafer can be suppressed by performing a multi-step wafer rinsing process under such conditions.

Although not shown diagrammatically, experiments have been conducted to confirm the fact that the flow rate (L/min) of the pure water supplied to the wafer affects the surface potential of the wafer, as well as the rotational speed of the wafer. Therefore, if a rinsing step is repeated in such a manner that the subsequent rinsing step is performed at a lower flow rate of pure water supplied to the wafer than that in the preceding rinsing step, then the surface potential of the wafer will come to decrease (approach 0 V) each time the rinsing step is performed.

The first cleaning unit 52 and the second cleaning unit 54 are each a roll sponge-type substrate cleaning apparatus as shown in FIG. 3. Instead of this type, a pen sponge-type substrate cleaning apparatus may be used as the first cleaning unit 52 and/or the second cleaning unit 54. For example, the roll sponge-type substrate cleaning apparatus may be used as the first cleaning unit 52, and the pen sponge-type substrate cleaning apparatus may be used as the second cleaning unit 54.

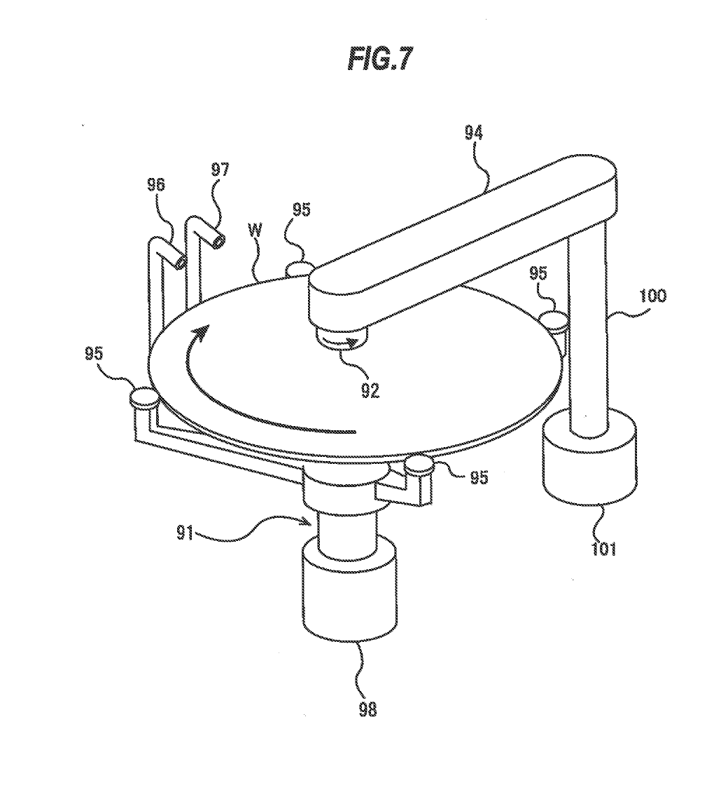

FIG. 7 is a perspective view of a pen sponge-type substrate cleaning apparatus. As shown in FIG. 7, the substrate cleaning apparatus of this type includes a substrate holder 91 for holding and rotating a wafer W, a pen sponge 92, an arm 94 for holding the pen sponge 92, a pure water supply nozzle 96 for supplying pure water onto the upper surface of the wafer W, and a cleaning liquid supply nozzle 97 for supplying a cleaning liquid (or a chemical liquid) onto the upper surface of the wafer W. The pen sponge 92 is coupled to a rotating device (not shown) disposed in the arm 94, so that the pen sponge 92 is rotated about a vertically-extending central axis.

The substrate holder 91 includes a plurality of (e.g., four as illustrated in FIG. 7) chucks 95 for holding the periphery of the wafer W. The wafer W is held in a horizontal position by means of the chucks 95. The chucks 95 are coupled to a motor 9 so that the wafer W, held by the chucks 95, is rotated about its own axis by the motor 98.

The arm 94 is disposed above the wafer W. The pen sponge 92 is coupled to one end of the arm 94, and a pivot shall 100 is coupled to the other end of the arm 94. The pivot arm 100 is coupled to a motor 101 serving as an arm rotating device for causing the arm 94 to pivot about the pivot shaft 100. The arm rotating device may include a reduction gear or the like in addition to the motor 101. The motor 101 is configured to rotate the pivot shaft 100 through a predetermined angle to thereby cause the area 94 to pivot in a plane parallel to the wafer W. As the arm 94 pivots, the pen sponge 92, supported by the arm 94, moves outwardly in a radial direction of the wafer W.

Cleaning of the wafer W is performed in the following manner. First, the wafer W is rotated about its axis. Next, the cleaning liquid is supplied from the cleaning liquid supply nozzle 97 onto the upper surface of the wafer W. In this state, the pen sponge 92 is rotated about the vertically-extending axis and is brought into sliding contact with the upper surface of the wafer W. Further, the pen sponge 92 oscillates in the radial direction of the wafer W. The pen sponge 92 is rubbed against the upper surface of the wafer W in the presence of the cleaning liquid to thereby scrub the wafer W.

After the scrub cleaning of the wafer W, in order to wash the cleaning liquid away from the wafer W, the pure water is supplied from the pure water supply nozzle 96 onto the upper surface of the rotating wafer W to thereby rinse the wafer W. The rinsing of the wafer W may be performed while rubbing the pen sponge 92 against the wafer W or while keeping the pen sponge 92 away from the wafer W.

While the above-described embodiments of the substrate cleaning method include the step of scrub-cleaning the wafer W with a scrubbing tool (a roll sponge or a pen sponge) while supplying the cleaning liquid onto the wafer W, it is also possible to perform cleaning of the wafer W by merely supplying a cleaning liquid onto the wafer W.

In the above-described embodiments the substrate processing method is applied to a substrate cleaning method. The method of the present invention can also be applied to a method of drying a substrate. For example, the present invention can be applied to a substrate drying method comprising supplying pure water (or ultrapure water) onto a substrate surface while rotating the substrate at a low speed, and then rotating the substrate at a high speed to spin-dry the substrate. Furthermore, the present invention can be applied to a substrate processing method which involves supplying a liquid comprising pure water (e.g., ultrapure water) onto a substrate. For example, the present invention can be applied to a substrate processing method which comprises supplying a chemical liquid, diluted with ultrapure water, to a wafer while rotating the wafer. Also in this case, the electrostatic charge of the wafer can be suppressed.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims and equivalents.

What is claimed is:

1. A substrate processing method comprising:
performing a first processing step of supplying a liquid containing pure water onto a substrate while rotating the substrate; and then
performing a second processing step of supplying the liquid onto the substrate, while rotating the substrate, under a condition in which a rate of increase in a surface potential of the substrate is lower than that in the first processing step.

2. The substrate processing method according to claim 1, wherein a rotational speed of the substrate in the second processing step is lower than that in the first processing step, or a flow rate of the liquid supplied to the substrate in the second processing step is lower than that in the first processing step.

3. The substrate processing method according to claim 1, wherein the liquid is pure water.

4. The substrate processing method according to claim 3, wherein the pure water is ultrapure water having a specific resistance of not less than 15 MΩ•cm.

5. The substrate processing method according to claim 1, wherein the liquid is a chemical liquid diluted with ultrapure water.
